(19) United States
(12) Patent Application Publication
(10) Pub. No.: US 2025/0138106 A1
(43) Pub. Date: May 1, 2025

(54) TEST SYSTEM COMPRISING BASIC CONVERTERS AND BOOST CONVERTER

(71) Applicants: AVL List GmbH, Graz (AT); AVL Set GmbH, Wangen im Allgäu (DE)

(72) Inventors: Martin SCHMIDT, Langen (DE); Alexander SCHMITT, Grünkraut (DE); Sven SEIFERT, Stephanskirchen (DE)

(73) Assignees: AVL List GmbH, Graz (AT); AVL Set GmbH, Wangen im Allgäu (DE)

(21) Appl. No.: 18/835,360

(22) PCT Filed: Feb. 1, 2023
(86) PCT No.: PCT/AT2023/060024

§ 371 Date: Aug. 2, 2024

(30) Foreign Application Priority Data
Feb. 2, 2022 (AT) A 50054/2022

(51) Int. Cl. G01R 31/40; G01R 31/385; G01R 31/396

(52) U.S. Cl. CPC G01R 31/40; G01R 31/385; G01R 31/396

(57) ABSTRACT

Test system (10) for simultaneous testing of several batteries, in particular high-voltage batteries, comprising: a DC voltage intermediate circuit (22), several basic converters (1a-1h) connected to the DC voltage intermediate circuit (22), each of which is switchably connected to a test channel (4a-4h) via a connection line (24a-24h), a boost converter (2a, 2b) connected to the DC voltage intermediate circuit (22) which, during operation of the test system (10), is switchable to different connection lines (24a-24h) to at least one of the test channels (4a-4h) via a boost line (26a, 26b) and one connection node (18a-18h), a control unit (27) for controlling the basic converters (1a-1h) and the boost converter (2a, 2b) according to a desired power transfer; wherein each connection line (24a-24h) comprises a safety-related switch (6a-6h) between test channel (4a-4h) and connection node (18a-18h).

The invention relates to a test system for simultaneous testing of several batteries, in particular high-voltage batteries, and a method for testing several units under test with a test system.

The demand for electrical test systems is currently increasing sharply due to the electrification of various fields of technology which were not previously electrified. Test systems can be configured to simulate the loads of the life cycle of a unit under test and are capable of charging and/or discharging a device connected to a test channel with a power as required by the respective test method. This applies to each individual test channel and each individual unit under test. Of particular interest is the testing of batteries. Battery test methods often involve large differences between the test powers required at different times. Often, only a low charging or discharging power is required for longer periods of time, while a particularly high charging or discharging power is required on an individual unit under test for short periods of time.

In the known test systems, electrical converters are used to provide the required transfer powers. In each case, a converter is coupled with a test channel. In order to cover the power requirement of each unit under test, the converters are designed for the maximum power to be provided on the respective test channel. Such converters therefore have to cover a large power range and are therefore particularly expensive. However, in many applications the maximum power range is only used for very short periods of time. However, with such a one-to-one coupling between converter and test channel, it is not possible to use exclusively low-cost converters with a lower power range due to the power range required for the test.

In principle, it is not ruled out that a required power may be provided by more than one converter. In this way, a high power could be transferred within a short period of time. However, if there is a possibility in test systems that a high power in the range of kW or MW will be transferred within a short period of time, high safety requirements must be met to prevent the risk of a faulty connection and a resulting short circuit. A simple coupling of several converters in order to transfer additional power when required leads to very complex safety systems, even with a few converters, whereby a high level of complexity is detrimental to the safety of the test system due to the associated risk of failure of individual parts.

It is therefore the object of the invention to remedy, at least in part, the disadvantages described above in a cost-effective and simple manner. In particular, the object of the present invention is to provide a test system for simultaneous testing of several units under test which can be produced more cost-effectively than existing test systems without compromising safety.

This object is achieved by a test system with the features of claim 1 and a method for testing one or more units under test according to claim 17. Further features and details of the invention are disclosed in the dependent claims, the description and the drawings. Naturally, features and details described in connection with the method according to the invention also apply in connection with the test system according to the invention and vice versa, so that with regard to disclosure mutual reference is or can always be made to the individual aspects of the invention.

According to a first aspect, the invention provides a test system for simultaneous testing of several batteries, in particular high-voltage batteries, comprising: a DC voltage intermediate circuit, several basic converters connected to the DC voltage intermediate circuit, each of which is switchably connected to a test channel via a connection line, a boost converter connected to the DC voltage intermediate circuit which, during operation of the test system, is switchable to different connection lines to at least one of the test channels via a boost line and one connection node, a control unit for controlling the basic converters and the boost converter according to a desired power transfer; wherein each connection line comprises a safety-related switch between test channel and connection node.

A test system is understood to be a device for simultaneous testing of physical properties of several units under test. In particular, the test system is suitable for testing the electrical properties of units under test at different temperatures. Possible units under test include for example batteries, especially high-voltage batteries, such as those used for example in electrically powered vehicles. Batteries are understood to be both individual cells, cells connected to form modules and modules connected to form packs. Furthermore, it is possible to use the test system to test inverters, fuel cells, drive trains, DC/DC converters, chargers or other devices transferring electrical power. Preferably, the test system is a power electronics test system.

A high-voltage battery is a storage device for electrical energy. It consists of several interconnected elements and a few to thousands of battery cells or cell blocks connected in parallel and in series.

A DC voltage intermediate circuit is a DC voltage circuit configured to transmit electrical power between different units of the test system. The voltage provided by the DC voltage intermediate circuit should be as constant as possible even under load and can for example be 750V. The DC voltage intermediate circuit can also comprise more than two voltage levels and thus a multi-level topology. Alternatively or additionally, a DC current intermediate circuit can be used instead of a DC voltage intermediate circuit.

A basic converter refers to an electrical circuit that converts a DC voltage supplied at the input into a DC voltage with a higher, lower or inverted voltage level and is designed to transfer a basic voltage level and/or a basic power level via its output. In addition to the application of converting a DC voltage into a different DC voltage, the basic converter can in principle also be designed to convert an AC voltage into a DC voltage, an AC voltage into a different AC voltage or a DC voltage into an AC voltage. The conversion takes place with the help of a power electronic circuit and one or more energy storage devices. A basic supply power can for example be between 20 kW and 300 kW. Basic converters are fundamentally configured to convert electrical power bidirectionally.

A connection line is an electrical line that is configured to connect a basic converter to a test channel. The connection line is preferably multi-pole in design.

A test channel is a device that is used to connect a test object (unit under test, UTT) for testing. A unit under test can be connected via several test channels. The test channel can be part of a test facility. The test facility can for example be a battery test bench, a fuel cell test bench, a charger test bench, a powertrain test bench or a test bench for testing DC-DC converters. A test channel can be multi-pole in design.

A boost converter, like the basic converter, refers to an electrical circuit that converts a DC voltage supplied at the input into a DC voltage with a higher, lower or inverted voltage level. Boost converters are also fundamentally designed to convert electrical power bidirectionally and can be designed identically to basic converters. Preferably, however, boost converters are designed in such a way that they transfer a power level at their output which, at a voltage level that matches the basic converter, is above the basic power level.

Operation of the test system is understood to mean that a unit under test is connected to the test system and a test run is carried out on the test system. A power transfer to or from the unit under test can hereby take place, or the test system is in a state in which no power transfer to or from the unit under test takes place. The transfer of power is generally not constant. The characteristic that a boost converter can be connected during the operation of the test system thus also includes necessary safety devices that enable it to be switched on and off without damaging the test system or harming an operator of the test system.

A boost line is an electrical line starting from a boost converter. Several connection lines are switchably connected to the boost line. The boost line can consist of several partial sections, which are for example connected by nodes. In particular, it may be the case that only partial sections of the boost line are switchably connected to the several connection lines. It is important to ensure that only one or no connection line is connected to the boost line during the operation of the test system. If several connection lines are connected to the boost line at the same time during operation of the test system, there is a risk of unintentional voltage transfer, if different voltages are applied to the respective connected connection lines.

A connection node is a point in the electrical network of the test system where two connections of the connection line and a connection of the boost line meet, whereby the current can branch at this point. At the connection node, a current flowing in the connection line can thus be superimposed on a current flowing in the boost line.

The control unit is configured to control the basic converter and the boost converter(s), i.e. to adjust the power to be transferred by the converters. For this purpose, the control unit is signal-technically coupled with the converters. The control unit knows the content of the storage unit and the setpoint values for current and/or voltage and/or power and measures or collects the corresponding actual values. Furthermore, the control device can be configured to calculate the current or future setpoint values for pre-control of a feed into the DC voltage intermediate circuit (e.g. active front-end converter) and/or the storage device.

A power transfer can be positive, negative or zero, i.e. it includes both a power output and a power consumption.

A safety-related switch is designed according to safety-related design principles that must be adhered to in order to minimise the risk of malfunction. Safety-related switches are designed in particular to detect or make detectable their own switching status and/or a malfunction on their part.

Preferably, in the test system according to the invention, the DC voltage intermediate circuit is connected to a power supply grid via a mains inverter.

The mains inverter converts a voltage available on the test bench, such as a multi-phase mains voltage, into a DC voltage which is referred to as an intermediate circuit voltage. The mains inverter can be a rectifier (AC-DC converter, active front-end converter), for example a switched bridge rectifier. The voltage conversion is in particular bidirectional. Converting the AC voltage to a DC voltage results in more accurate actuation due to a smoother input voltage.

A power supply grid is a network for the transmission and distribution of electrical energy. The power supply grid is preferably an AC grid, but can also be a DC grid. If the grid is a DC grid, a DC/DC converter is provided as a mains inverter that converts the mains voltage into an appropriate intermediate circuit voltage.

A further advantage can be achieved if the test system also includes a storage device that is configured to transfer power to at least one of the test channels or from at least one of the test channels, wherein the storage device is connected to the DC voltage intermediate circuit directly or via additional power electronics.

The storage device is a device for storing electrical energy and can comprise accumulators, supercapacitors or also other physical or chemical energy storage devices. The storage device is used to stabilise the DC voltage intermediate circuit for situations in which the test system takes a lot of power from the DC voltage intermediate circuit or releases a lot of power into the DC voltage intermediate circuit.

It is also advantageous if the storage device comprises a chopper.

A chopper is a switchable resistor that converts power into heat when needed, thus extracting electrical power from the test system. The chopper can be actively or passively controlled.

It is also advantageous if the test system also includes an active front-end converter which is configured to transfer power to or from the power supply grid.

The active front-end converter is a controllable rectifier with bidirectional power transfer between AC and DC and the possibility of feeding power back into the power supply grid. If the test system is connected to a power supply grid in such a way that current can be fed back from the test system into the power supply grid, it is necessary that the test system includes an active front-end converter.

In particular, it may be the case that the basic converter is operable in a first power range and the boost converter is operable in a second power range, and the first power range is smaller than the second power range.

In test systems for testing high-voltage batteries, the first power range can for example cover outputs of up to 300 kW and the second power range can cover outputs of up to 750 kW. Converters with particularly large power ranges are more expensive to purchase than those with lower power ranges. A cost advantage in the production of the test system can be further enhanced by the different-sized power ranges.

It is also advantageous if the ratio of the number of boost converters to the number of basic converters in the test system is between ½ and ⅙, and preferably between ⅓ and ⅕.

The ratio of the number of boost converters to the number of basic converters can be optimised according to the utilisation of the boost converters. For this purpose, a boost converter should be available if it is needed in order to provide higher transfer powers, but should have short down times during which its output does not need to be used. The ratio depends on the respective application and the power ranges of the basic converter and the boost converter. In test systems for high-voltage batteries and the associated test runs, a ratio of 4 basic converters per boost converter can represent a cost-optimised compromise.

It is also advantageous if a voltage measuring device is arranged above each of the safety-related switches.

The voltage measuring device is designed to measure the voltage on both sides of a switch, so that the switch can be prevented from closing in the event of undesirable voltage differences on both sides of the switch. This measurement is preferably carried out on all switches of the test system. The data recorded by the voltage measurement devices are transmitted to the control unit.

A further advantage can be achieved if at least one of the safety-related switches comprises a parallel connection of several switches.

The parallel connection can in particular consist of a resistance-coupled switch and a resistance-free switch. If the resistance-coupled switch is closed first, voltage differences on both sides of the safety-related switch are equalised in such a way that no excessive currents flow which can cause damage or falsify the test result. In the closed position, the entire current is conducted with practically no loss via the resistance-free switch which is then closed.

It is also advantageous if at least one of the safety-related switches is configured to switch a direct current that is superimposed with ripple current.

In this particular embodiment of the invention, the corresponding safety-related switch comprises a parallel connection of several switches, wherein one of the switches of the parallel connection is designed to conduct direct current and another switch of the parallel connection is designed to conduct alternating current. In test systems for high-voltage batteries, the currents to be transferred are often direct currents (DC component) over which an alternating current or ripple current (AC component) is superimposed. The ripple currents can be generated by modulating the setpoint of the boost converter. Usually, the majority of the power is transmitted via direct current, while a smaller part is transmitted via alternating current or ripple current. In order to ensure a realistic test situation, a transfer of both components is necessary. A simple switch for high power outputs is generally not suitable for transmitting such superimpositions of DC and AC components, since cables with a large cable diameter are required for the high currents of the DC component, and AC components of the current can only flow on the surface of such cables. By connecting an AC switch and a DC switch in parallel, better transmission of both components is possible. Because of the different current strengths of the AC components and the DC components, the AC switch can be designed for the transmission of smaller currents than the DC switch. In particular, such a parallel connection can be designed to close the AC switch first and then the DC switch in a switching process.

Furthermore, it may be preferable that the storage device comprises a fast storage with fast access time and a slow storage with slow access time, and the fast storage comprises a lower capacity than the slow storage.

The combination of fast storage and slow storage enables a cost-optimised use of both systems. While fast storage systems can absorb and release short-term load changes, slow storage systems generally enable a more low-loss storage of electrical energy at lower costs. Supercapacitors, for example, can be used as fast storage systems, and accumulators as slow storage systems.

Particularly preferably, the boost line comprises a boost switch for switching a boost power to at least one of the test channels.

The boost switch can be designed as a contactor switch, but is preferably a power electronics semiconductor switch such as an IGBT or MOSFET. The power electronics semiconductor switch can include Si, GaN, SiC or other semiconductor materials as a semiconductor material. When switching the boost power onto the basic power, a short switching time is helpful in order to follow the voltage curve specified in a test run as closely as possible and to be able to disconnect even in the event of rapid changes in the power to be transferred. Due to the fast switching times of a power electronics semiconductor switch, it is made possible to connect the boost line to one of the several connection lines at any time during operation, even during load changes, without voltage. Power electronics semiconductor switches achieve a switching time in the range of nanoseconds, whereas the switching times of contactor switches are in the range of about 10 milliseconds and are therefore significantly slower. To prevent several test channels from being shorted together via the boost line, the boost switches preferably have a safety-related input. The safety-related input can prevent or allow the switching state of the boost switch to be changed. Such a safety-related input can be implemented in a simple way, analogously to a safe torque-off switch of a drive converter. Only if the safety-related input allows a change in the switching state can the switch be closed or opened.

The control unit can also be configured in such a way that only one boost switch may be closed at a time. A channel would therefore only be released for connection via the boost switch when it is ensured that no further channel can be connected. A safety-related input does not fundamentally delay the switching time of the boost switch.

Furthermore, the basic converter and/or the boost converter(s) preferably each comprise back-up capacitors and an output capacitance of the back-up capacitors of the boost converter or the boost converters is less than the output capacitance of the back-up capacitors of the basic converters.

The output capacitances of the converters support the output voltage and keep it stable. However, if one of the basic converters or one of the boost converters is not connected to a test channel without voltage, a current flows between the test channel and the back-up capacitor. The current strength depends on the size of the connected output capacitance and can also influence the test run. Such faulty connections can occur in particular in the case of faulty voltage measurements. It is therefore advantageous to keep the capacitances that are not arranged directly on the test channel as small as possible. This includes in particular the output capacitances of the boost converters that are switched on regularly. The boost converter can also comprise a multi-level converter. In this case, an output capacitance can be dispensed with.

It is also advantageous if at least one of the basic converters is galvanically isolated from the DC voltage intermediate circuit.

Galvanic isolation is understood to mean the avoidance of electrical conduction between two circuits between which power or signals are to be exchanged. In galvanic isolation, the electrical potentials are separated from each other and the circuits are then potential-free with respect to each other. Preferably, the boost converter is also galvanically isolated from the DC voltage intermediate circuit. Particularly preferably, all basic converters and/or all boost converters are galvanically isolated from the DC voltage intermediate circuit. Galvanic isolation provides greater safety, enables more accurate measurements of voltage, independently of the DC voltage intermediate circuit, and prevents electromagnetic interference and unwanted interactions between test channels.

A further advantage can be achieved if the safety-related switches are signal-technically connected to a safety system.

In particular, the safety system controls the safety-related switches. An isolation monitor is used to measure whether a galvanic isolation of basic converters and/or boost converters is intact. If a fault is measured in connection with one or more galvanic isolations, the safety system opens safety-related switches associated with the fault and/or prevents them from being closed. In addition, the control device is configured to control the safety-related switches.

It is also conceivable that the test system comprises a second boost converter connected to the DC voltage intermediate circuit which is connectable to the boost line during operation of the test system.

A second boost converter may be designed in the same way as the first boost converter or in a different way. The second boost converter can be connected to a second boost line, which can in turn can be connected to at least one of the test channels via a connection node leading to different connection lines. The connection of the second boost converter to the boost line of the first boost converter can be effected via a connector switch connected to both boost lines. Before connection, the voltage is measured via the connector switch and, if necessary, regulated in such a way that the connection is voltage-free. In addition to a second boost converter, the test system can include other boost converters as required, which can be connected and switched on in the same way as the first two boost converters.

According to a second aspect, the invention provides a method for testing one or more units under test with a test system, preferably according to one of the preceding claims, comprising the steps:
a) connecting a device under test to one of the test channels;
b) starting a test run on the device under test;
c) sending a power request for a test channel to the control unit;
d) checking whether the requested power is greater in amount than the power transferable by the basic converter;
e) connecting the boost converter to one of the test channels if the requested power is greater in amount than the power transferable from the basic converter;
f) transferring the requested power via the basic converter and the boost converter.

A unit under test may be any unit that releases or absorbs electrical energy. In particular, units under test may include the following: batteries, preferably rechargeable batteries, particularly preferably high-voltage batteries, inverters, fuel cells, electric powertrains, DC/DC converters and electric chargers.

In a test run, the unit under test is operated under different conditions in order to test its function and performance. In the test run, the sequence of the various conditions is defined before the start of the test run. In the case of high-voltage batteries, charging cycles and discharge cycles can for example follow one another in the test run in the way that is expected during the service life of the high-voltage battery. Usually, in a test facility with several test channels, several test runs are started simultaneously or at short intervals. In this case, it is advantageous, if the test runs are started in such a way, that during the entire test duration of all test runs, only one of the test channels sends a power request that exceeds the power of the basic converter connected to the respective test channel, and thus only one of the test channels requires the connection of the boost converter and/or boost converters in order to transfer the requested power.

Particularly preferably, test runs to be carried out on different test channels are coordinated with each other in such a way that the power consumption of one test channel corresponds to the power output of another test channel. In this way, less of a load is placed on the DC voltage intermediate circuit and an overall power transfer is reduced. This can reduce the costs of operating the test facility. Of course, such optimisation is only possible in the case of units under test where power transfer in both directions is possible, such as high-voltage batteries for example.

In the method according to the second aspect of the invention, the power request is preferably sent to the control unit at least 1 μs, preferably at least 100 μs, prior to providing the power.

By sending the power request prior to providing the power, the control unit can equalise voltages between parts of the test system to be connected and thus improve the switching processes.

The invention also provides a computer program product comprising commands which, when the program is run on a computer, cause it to carry out method according to one of claims 17 or 18.

Finally, the invention provides a computer-readable medium on which the computer program product according to claim 19 is stored.

Further advantages, features and details of the invention are explained in the following description, in which embodiments of the invention are described in detail with reference to the drawings. The features mentioned in the claims and in the description may each be essential to the invention individually or in any combination. It is shown schematically:

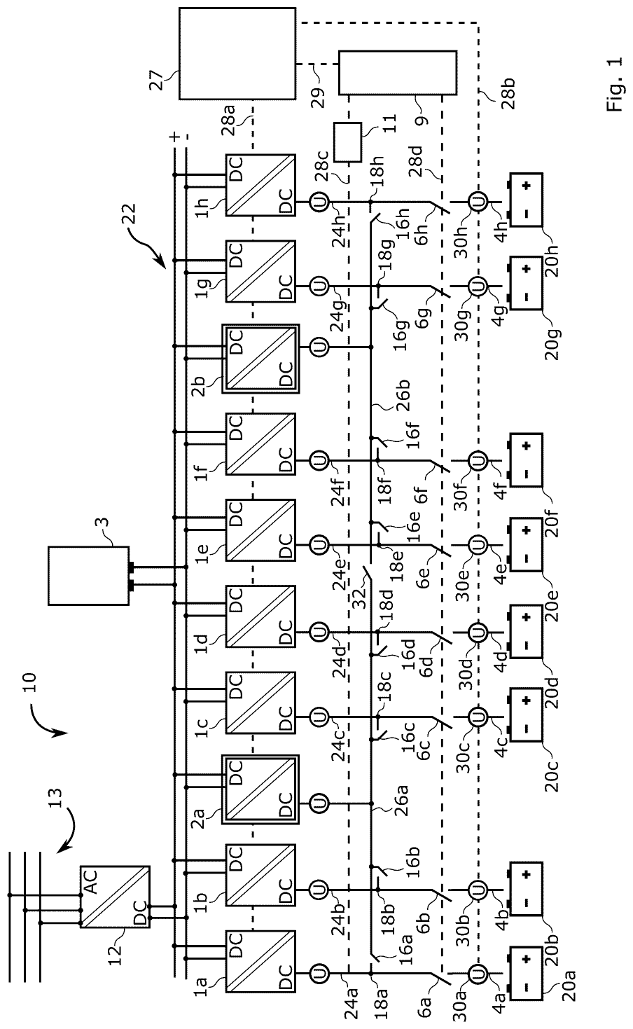

FIG. 1 a schematic of a test system according to the invention according to a particular embodiment of the invention; and

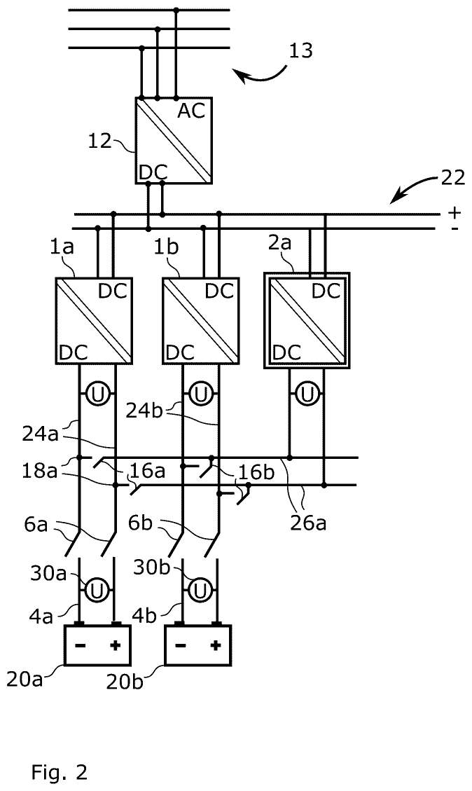

FIG. 2 an enlarged section of the schematic of FIG. 1, on which additional details are shown.

FIG. 1 shows a schematic of a test system 10 according to the invention in a particular embodiment of the invention.

The test system 10 is configured for simultaneous testing of several units under test 20a-20h. The test system comprises a DC voltage intermediate circuit 22 to which essential elements of the test system 10 are connected. The DC voltage intermediate circuit 22 is 2-pole in design. Furthermore, the test system 10 comprises several basic converters 1a-1h connected to the DC voltage intermediate circuit 22. The basic converters 1a-1h are each connectable to a test channel 4a-4h via a connection line 24. There is thus a one-to-one coupling between basic converter 1a-h and test channel 4a-h. Each test channel 4a-4h is electrically connected to exactly one of the basic converters 1a-1h.

In addition to the eight basic converters 1a-1h, the test system 10 also comprises a first boost converter 2a connected to the DC voltage intermediate circuit 22 and a second boost converter 2b connected to the DC voltage intermediate circuit 22. The boost converters 2a-2b can in each case be switched to different connection lines (24) to the test channels 4a-4h via a boost line 26a, 26b and one connection node 18a-18h. Specifically, the connection is made via boost switches 16a-16h, with which a boost line 26a, 26b is connected switchably to several connection lines. The connection lines 24 are shown in FIG. 1 as single-pole for reasons of clarity, but are generally at least two-pole in design. Specifically, the boost converter 2a can be connected to the test channels 4a-4d via the boost line 26a and the boost converter 2b can be connected to the test channels 4e-4h via the boost line 26b, at least if there is no coupling of the two boost lines 26a-26b, which will be discussed below.

Each connection line 24a-24h has a safety-related switch 6a-6h between test channel 4a-4h and connection node 18a-18h. Basically, each of the safety-related switches 6a-6h is designed in such a way that each individual line of the multi-pole connection lines 24a-24h can be switched. The position of the safety-related switches 6a-6h is arranged on a connection line 24a-24h between test channel 4a-4h and connection node 18a-18h.

During operation of the test system 10, the boost converter 2a can be connected via a boost line 26a and one connection node 18a-18d to each of the connection lines 24a-24d, and via these to the respective test channels 4a-4d. Accordingly, the boost converter 2b can be connected via the boost line 26b and the connection node 18e-18h to the connection lines 24e-24h, and via these to the respective test channels 4e-4h. While the boost lines 26a, 26b can be connected to several of the connection lines 24a-24h, in order to prevent short circuits between the connection lines it is specified that each of the boost lines 26a, 26b can be connected to only one of the connection lines 24a-24h at any time.

Through the 2 boost converters 2a, 2b and the 2 boost lines 26a, 26b, the test system 10 enables the supply of two separate test channels 4a-4h, one from the group of test channels 4a-4d and one from the group 4e-4h. However, the boost lines 26a, 26b are also switchably connected to each other via a coupling switch 32 and can be connected to each other by this. This makes it possible to combine the power output of a basic converter 1a-1h with the power output of the first boost converter 2a and the power output of the second boost converter 2b. This allows further increased power to be transferred to or from a test channel 4a-4h. The coupling switch 32 is also connected to the safety system 9, which also prevents a coupling of several test channels 4a-4h with each other via a boost line 26a, 26b.

The test system 10 also comprises a control unit 27 for controlling the basic converters 1a-1h and the boost converters 2a, 2b according to a desired power transfer. For this purpose, the control unit 27 is connected via a first signal line 28a to the basic converters 1a-1h and the boost converters 2a, 2b and via a second signal line 28b to voltage measuring devices 30a-30h, which are configured to measure the voltages applied to the test channels 4a-4h. The first signal line 28a is configured to send control signals to the basic converters 1a-1h and the boost converters 2a, 2b. The second signal line 28b is used to measure a voltage present at the respective test channel 4a-4h. The signal lines 28a, 28b and 28c are shown as dashed lines. In addition, the control unit 27 is connected via a connecting cable to the safety system 9. Alternatively, the safety system 9 can also be integrated directly into the control unit 27. The safety system 9 is designed to ensure the safety of the persons operating the test system and the safety of the units under test 20a-20h. It is connected to the connection lines 24a-24h via a signal line 28c and an isolation monitor 11. The isolation monitor 11 is designed to cyclically measure whether the galvanic isolation of the basic converters 1a-1h and the boost converters 2a, 2b from the DC voltage intermediate circuit is functioning. Faults in the galvanic isolation would lead to detectable fluctuations in the connection lines 24a-24h. Furthermore, the safety system 9 is connected via a signal line 28d to the safety-related switches 6a-6h which are in each case arranged between a test channel 4a-4h and a connection node 18a-18h. The safety-related switches 6a-6h are usually switched by means of a switching signal sent from the control unit 27 to the safety system 9 via the connecting cable 29. After testing and enabling by the safety system 9, the safety system 9 then switches the safety-related switch 6a-6d according to the received switching signal. Independently of this, the safety system 9 can open any of the safety-related switches 6a-6h and thus interrupt the electrical connection to the test channels 4a-4h and the units under test 20a-20h. This can in particular be necessary if a fault in the functioning of the galvanic isolation of the basic converters 1a-1h and/or the boost converters 2a, 2b is detected.

The safety system 9 is also connected to the boost switches 18a-18h via a further signal line (not shown). The boost switches 16a-16h, which are configured to connect boost power. The safety system 9 thereby has the function of ensuring that only one, or none, of the test channels 4a-4h is connected to a boost line 26a, 26b at any given time. For this purpose, the boost switches 16a-16h are power semiconductor switches equipped with a safety torque-off switch (STO switch). The STO switch does not delay the very fast switching times of the power semiconductor switches, but can prevent the boost switch 16a-16h equipped with it from being closed at all. The safety system can only enable one of the STO switches at any given time, thus preventing more than one boost switch 16a-16h per separate boost line 26a, 26b from being closed. This prevents a short circuit between two test channels 4a-4h and an associated unwanted power transfer with potential damage to the test system 10 and injury to technical personnel.

Each of the connection lines 24a-24h leads from a basic converter 1a-1h to a test channel 4a-4h and, if connected, to a unit under test 20a-20h. Each connection line 24a-24h has a safety-related switch 6a-6h between test channel 4a-4h and connection node 18a-18h. This arrangement allows both the power provided by the basic converters 1a-1h and the increased power provided by the boost converters 2a, 2b to be switched in a safety-oriented manner.

The DC voltage intermediate circuit 22 is connected via a mains inverter 12 to a three-phase power supply grid 13 which supplies the DC voltage intermediate circuit 22 with electrical power and via which electrical power can be dissipated. For this purpose, the mains inverter 12 can be designed as an active front-end converter. A galvanic isolation of the mains inverter 12 as shown in FIG. 1 is not absolutely necessary if all basic converters 1a-1h and all boost converters 2a, 2b are galvanically isolated.

The test system 10 also includes a storage device 3 connected to the DC voltage intermediate circuit 22 which is configured to transfer power to and from the test channels 4a-4h via the basic converters 1a-1h and the boost converters 2a, 2b. The storage device can comprise a battery, a supercapacitor and/or a chopper.

In this embodiment, the test system has eight basic converters 1a-1h and two boost converters 2a, 2b. The ratio of the number of boost converters 2a, 2b to the number of basic converters 1a-1h is thus ¼.

In order to test the error-free functioning of the test system 10, electrical measuring devices are arranged at various positions. In particular when operating the test system in the high-power range, a voltage measurement must be carried out above each switch in order to avoid abrupt compensating currents with high powers. For this purpose, a voltage measuring device 30a-30h is provided above each of the switches, in particular above each safety-related switch, which is configured to measure the voltage on both sides of the switch and to ensure that both sides of the switch are at the same potential. In principle, a current measuring device can also be provided at each position where a voltage measuring device 30a-30h is provided. This makes it possible in addition to measure the power transfer at the respective point. For reasons of clarity, not all the voltage measuring devices 30a-30h are shown in FIG. 1.

FIG. 2 shows an enlarged section of the circuit diagram of FIG. 1 on which additional details are shown. As described in connection with FIG. 1, for reasons of clarity some features are not shown in detail in FIG. 1. In particular, FIG. 2 shows in detail that the connection lines 24a, 24b leading from the basic converters 1a, 1b, as well as the DC voltage intermediate circuit, are two-phase in design. Furthermore, it is shown in detail that the safety-related switches 6a, 6b are configured to switch each of the phases of connection lines 24a, 24b separately. If the safety-related switches 6a, 6b comprise a parallel connection of several switches, each of the phases has such a parallel connection of several switches, although this is not shown in the particular embodiment of the invention represented here. Furthermore, the boost line 26a is two-phase and the boost switch 16a, 16b is designed to switch the multi-phase boost line. The voltage measuring devices 30a, 30b are arranged in such a way that they measure the voltage between the individual phases of the two-phase test channel. In the section not shown in FIG. 2, the test system 10 is designed in the same way as in the section shown in FIG. 2.

### LIST OF REFERENCE SIGNS

1a-1h basic converter
2a, 2b boost converter
3 storage device
4a-4h test channel
6a-6h safety-related switch
9 safety system
10 test system
11 isolation monitor
12 mains inverter
13 power supply grid
16a-16h boost switch
18a-18h connection node
20a-20h unit under test
22 DC voltage intermediate circuit
24a-24h connection line
26a, 26b boost line
27 control unit
28a-28c signal line
29 connecting cable
30a-30h voltage measuring device
32 coupling switch

1. Test system for simultaneous testing of several batteries, in particular high-voltage batteries, comprising:
a DC voltage intermediate circuit,
several basic converters connected to the DC voltage intermediate circuit, each of which is switchably connected to a test channel via a connection line,
a boost converter connected to the DC voltage intermediate circuit which, during operation of the test system, is switchable to different connection lines to at least one of the test channels via a boost line and one respective connection node,
a control unit for controlling the basic converters and the boost converter according to a desired power transfer; wherein
each connection line comprises a safety-related switch between test channel and connection node.

2. Test system according to claim 1, wherein the DC voltage intermediate circuit is connected to a power supply grid via a mains inverter.

3. Test system according to claim 1, further comprising a storage device which is configured to transfer power to at least one of the test channels or from at least one of the test channels, wherein the storage device is connected to the DC voltage intermediate circuit.

4. Test system according to claim 1, wherein the storage device comprises a chopper.

5. Test system according to claim 2, further comprising an active front-end converter which is configured to transfer power to the power supply grid or from the power supply grid.

6. Test system according to claim 1, wherein the basic converter is operable in a first power range and the boost converter is operable in a second power range, and the first power range is smaller than the second power range.

7. Test system according to claim 1, wherein the ratio of the number of boost converters to the number of basic converters in the test system is between ½ and ⅙, and preferably between ⅓ and ⅕.

8. Test system according to claim 1, wherein a voltage measuring device is arranged above each of the safety-related switches.

9. Test system according to claim 1, wherein at least one of the safety-related switches comprises a parallel connection of several switches.

10. Test system according to claim 1, wherein at least one of the safety-related switches is configured to switch a direct current that is superimposed with ripple current.

11. Test system according to claim 1, wherein the storage device comprises a fast storage with fast access time and a slow storage with slow access time, and the fast storage comprises a lower capacity than the slow storage.

12. Test system according to claim 1, wherein the boost line comprises a boost switch for switching a boost power to at least one of the test channels.

13. Test system according to claim 1, wherein the basic converter and/or the boost converter(s) each comprises back-up capacitors and an output capacitance of the back-up capacitors of the boost converter or the boost converters is less than an output capacitance of the back-up capacitors of the basic converters.

14. Test system according to claim 1, wherein at least one of the basic converters is galvanically isolated from the DC voltage intermediate circuit.

15. Test system according to claim 1, wherein the safety-related switches are signal-technically connected to a safety system.

16. Test system according to claim 1, wherein the test system comprises a second boost converter connected to the DC voltage intermediate circuit which is connectable to the boost line during operation of the test system.

17. Method for testing one or more units under test with a test system, preferably according to claim 1, comprising the steps:
a) connecting a unit under test to one of the test channels;
b) starting a test run on the unit under test;
c) sending a power request for a test channel to the control unit;
d) checking whether the requested power is greater in amount than the power transferable by the basic converter;
e) connecting the boost converter to one of the test channels if the requested power is greater in amount than the power transferable from the basic converter;
f) transferring the requested power via the basic converter and the boost converter.

18. Method according to claim 17, wherein the power request is sent to the control unit at least 1 μs, preferably at least 100 μs, prior to providing the power.

19. Computer program product comprising commands which, when the program is run on a computer, cause it to carry out the method according to claim 17.

20. Computer-readable data medium on which the computer program product according to claim 19 is stored.
